(19) United States
(12) Patent Application Publication
(10) Pub. No.: US 2020/0245503 A1
(43) Pub. Date: Jul. 30, 2020

(54) AIR FLOW IMPEDANCE BALANCING IN ENCLOSURES

(71) Applicant: HEWLETT PACKARD ENTERPRISE DEVELOPMENT LP, Houston, TX (US)

(72) Inventors: David Chialastri, Houston, TX (US); Travis J. Gaskill, Houston, TX (US); Vincent W. Michna, Houston, TX (US); Nilashis Dey, Houston, TX (US); Patrick Raymond, Houston, TX (US)

(21) Appl. No.: 16/258,887

(22) Filed: Jan. 28, 2019

(51) Int. Cl. H05K 7/20; F25D 23/12

(52) U.S. Cl. CPC H05K 7/20727; G05D 23/00; F25D 23/12

(57) ABSTRACT

A method for balancing air flow impedance within an enclosure. The method includes determining a configuration of each hardware module of a plurality of hardware modules arranged in a housing of the enclosure. The method also includes determining impedance settings for a plurality of adjustable air flow impedance elements within the housing, based at least in part on the configurations of the plurality of hardware modules, that will balance air flow impedances of the plurality of hardware modules. The method further includes setting the plurality of adjustable air flow impedance elements according to the determined impedance settings.

### BACKGROUND

Electronic components (e.g., processing and memory components) included in enclosures, such as server chassis, generate heat during their operation. At raised temperatures, the electronic components may be susceptible to impaired performance, and in some instances, may fail. Accordingly, cooling systems have been implemented in many enclosures to maintain the electronic components at acceptable operational temperatures. Generally, cooling systems may utilize a cooling fluid to remove thermal energy from the electronic components. In some instances, the cooling fluid may be forced air generated by one or more fans to directly contact the electronic components or a heat sink thermally coupled thereto to transfer thermal energy from the electronic components to the cooling fluid.

### BRIEF DESCRIPTION OF THE DRAWINGS

The present disclosure is best understood from the following detailed description when read with the accompanying Figures. It is emphasized that, in accordance with the standard practice in the industry, various features are not drawn to scale. In fact, the dimensions of the various features may be arbitrarily increased or reduced for clarity of discussion.

FIG. 1 is a schematic of an enclosure, according to one or more examples of the disclosure.

FIG. 2 is a block diagram of a controller utilized in the enclosure of FIG. 1, according to one or more examples of the disclosure.

FIG. 3 is a flow chart depicting a method for balancing air flow impedance within an enclosure, according to one or more examples of the disclosure.

FIG. 4 is a flow chart depicting a method for determining an air flow impedance of each hardware module inserted into an enclosure, according to one or more examples of the disclosure.

FIG. 5 is a flow chart depicting a method for determining impedance settings for a plurality of adjustable air flow impedance elements within a housing, based on the configurations of a plurality of hardware modules, that will balance air flow impedances of the plurality of hardware modules, according to one or more examples of the disclosure.

### DETAILED DESCRIPTION

Illustrative examples of the subject matter claimed below will now be disclosed. In the interest of clarity, not all features of an actual implementation are described in this specification. It will be appreciated that in the development of any such actual implementation, numerous implementation-specific decisions may be made to achieve the developers' specific goals, such as compliance with system-related and business-related constraints, which will vary from one implementation to another. Moreover, it will be appreciated that such a development effort, even if complex and time-consuming, would be a routine undertaking for those of ordinary skill in the art having the benefit of this disclosure.

Further, as used herein, the articles “a” and “an” are intended to have their ordinary meaning in the patent arts, namely “one or more.” Herein, the term “about” when applied to a value generally means within the tolerance range of the equipment used to produce the value, or in some examples, means plus or minus 10% unless otherwise expressly specified. Moreover, examples herein are intended to be illustrative only and are presented for discussion purposes and not by way of limitation.

In some example computing systems, a multitude of hardware modules may be housed within a single enclosure or chassis. Moreover, the hardware modules in the enclosure may be of a variety of different types, such as power modules, storage modules, memory modules, and computing modules. Power modules may include, in some examples, one or more power supply devices to provide power to the other hardware modules in the electrical system. Storage modules, in some examples, may include a plurality of storage devices, such as hard-disk drives (HDDs) coupled to a tray or other insertable component. Computing modules may include a variety of computing devices, such as, for example, servers (e.g., rack servers, blade servers, nodes, etc.), accelerators, etc. Memory modules may include one or more memory devices storing instructions executable by the computing devices. The devices included in the multitude of hardware modules are generally constructed from one or more electronic components. Example electronic components may include, but are not limited to, central processing units (CPUs), graphics processing units (GPUs), and dual inline memory modules (DIMMs).

As electronic components (e.g., CPUs, GPUs, and DIMMs) decrease in size, hardware modules, such as servers, are in turn able to increase the number of such electronic components utilized. Likewise, racks, such as high-density server racks, have been constructed to house an increased number of servers for certain computing applications. Generally, the hardware modules (individually or as installed on a tray) may be inserted into an enclosure (e.g., server chassis) configured to house the hardware modules and the associated infrastructure. Generally, some, or all, of the hardware modules are arranged in the enclosure in a parallel orientation. The enclosure may be installed in the rack (e.g., high-density server rack) in a stacked arrangement with other enclosures containing like hardware modules.

In operation, the electronic components in the hardware modules may generate heat. Accordingly, the electrical system may implement a fluid-based cooling system, such as an air-cooling system, a liquid-cooling system, or a combination thereof, to reduce the temperature of the electronic components in the hardware modules to prevent impaired performance or failure of the respective electronic components included in each of the hardware modules. In air-cooling systems, fans, compressors, and/or air conditioners may be implemented to cool the electronic components.

Air-cooling systems, such as computer room air conditioner (CRAC) units, typically are not able to provide a sufficient cooling airflow through the high-density server racks. Accordingly, in such systems, one or more fans may be positioned within (e.g., at one end of) each enclosure to generate a sufficient air flow through the hardware modules via forced air. However, hardware modules mounted in the system typically impede this forced air flow to some degree. This is referred to as “air flow impedance” for present purposes.

Typically, different hardware modules may have different air flow impedances from one another, as the physical structure of each hardware module may vary. Thus, when different hardware modules are included within the same enclosure, less air will flow through the higher impedance modules than through the lower impedance modules, all other things being equal, as the air flow through the enclosure seeks a path of least resistance. Therefore, an issue can arise in which different modules are receiving different amounts of airflow (i.e., the enclosure has unbalanced airflow), possibly resulting in the higher impedance hardware modules being insufficiently cooled.

If each hardware module in the enclosure has its own dedicated fan(s) that provide it alone with airflow, then the above noted issue could be addressed by causing the fans of higher impedance hardware modules to operate at faster speeds than the fans of lower impedance hardware modules. Increasing the fan speed for higher impedance modules causes more air to flow through them, thus compensating for their greater air flow impedance. Thus, by tailoring the fan speed of each hardware module according to its particular airflow impedance, one can balance the amounts of air flowing through the hardware modules of the enclosure and ensure that all modules receive sufficient air to cool them. The operation of the fans at a faster speed may lead to increased noise and excessive energy consumption by the fans generating the forced air, and thus, results in inefficiency and increased costs of operation of the electrical system.

However, in systems in which a group of multiple hardware modules share the same set of fans (e.g., multiple hardware modules are fluidly coupled to one or more fans in an enclosure via a common air plenum), the approach of tailoring the fan speed of individual hardware modules may no longer work to mitigate the above-noted issue. In particular, if a higher impedance hardware module and a lower impedance hardware module share the same set of fans, increasing the operating speed of the fan(s) may have little effect on the amount of air flowing through the high impedance hardware modules. This is the case because, when the fan speed is increased, a greater proportion of the resulting increased air flow will be diverted through the low impedance module, since it presents the path of least resistance, and only a relatively small increase in airflow through the high impedance module will be realized. Thus, the lower impedance module will always have more air flowing through it than the higher impedance module regardless of the fan speed, and therefore the airflow will not be balanced between the hardware modules. Accordingly, modulating the fan speed to direct a certain amount of air flow through a particular hardware module in such an arrangement is generally ineffective.

Accordingly, examples of the present disclosure are directed to an enclosure in which multiple hardware modules share the same set of fans and including an air flow impedance system capable of altering the impedance of individual hardware modules and thereby balancing the air flow impedance of the hardware modules contained therein to increase the efficiency of the fans operating to cool the hardware modules. The air flow impedance system may include an adjustable air flow impedance element for each hardware module that is interposed in the airflow path of its corresponding hardware module so that it can increase the impedance of the hardware module above its intrinsic impedance (the intrinsic impedance being the impedance of the module absent the adjustable air flow impedance element). Particularly, in one or more examples of the present disclosure, a controller may communicate with the air flow impedance system and each hardware module inserted in the enclosure. The controller may determine the configuration of each hardware module inserted in the enclosure. Based on the determined configuration of each hardware module, the controller may determine impedance settings for adjustable air flow impedance elements of the air flow impedance system that will balance the air flow impedances of the plurality of hardware modules. The adjustable impedance elements may then be positioned according to the determined impedance settings. For example, suppose that three hardware modules that have a relatively high intrinsic impedance (e.g., compute modules) and one hardware module that has a relatively lower intrinsic impedance (e.g., a memory module) are installed in the enclosure; in that case, the controller may determine that it should increase an impedance setting of an air flow impedance element associated with the lower impedance module so as to effectively increase the total impedance through the module to match the impedance of the other modules.

In some examples, the controller may determine the configuration of each hardware module based on information related to each hardware module. The configuration may include an identification of the type of hardware module that is installed and may also include additional information such as which components are included in the module. For example, the information may be firmware stored on the hardware module. The firmware may be the instructions installed on the hardware module to operate the hardware module.

In some examples, the controller may determine the impedance settings for the adjustable air flow impedance elements based on the intrinsic impedances of the installed hardware modules. Based on the determined configuration of each hardware module, the controller may determine the intrinsic air flow impedance of each hardware module. For example, the controller may consult a database that lists intrinsic impedance values for particular types of hardware modules in particular combinations. As another example, the configuration information from the hardware module may explicitly identify an intrinsic impedance of the module. As another example, the controller may deduce or estimate an intrinsic impedance for a module based on its configuration information and a mathematical model. Based at least in part on the determined intrinsic air flow impedance of each hardware module, the controller may determine impedance settings for the adjustable air flow impedance elements that will improve a balance of the airflow among the modules. In particular, the controller may set the adjustable air flow impedance elements so as to increase the impedances of lower impedance modules towards the impedance of the highest impedance hardware module, which tends to improve the balance of air flow through all the modules. More specifically, in some examples, the controller may set the adjustable air flow impedance elements such that all of the hardware modules have the same impedance, with the impedance value to which the modules are all set being referred to herein as a “common air flow impedance”. In some examples, the controller specifies the common air flow impedance to be equal to the highest impedance value out of the intrinsic impedances of the installed hardware modules. The appropriate settings for the air flow impedance elements that will result in the desired impedances for their respective hardware modules may be determined by the controller by consulting a table or by a mathematical model.

In some examples, the controller may determine the impedance settings for the adjustable air flow impedance elements without explicitly determining the intrinsic impedances of the installed hardware modules. For example, the controller may determine impedance settings for the adjustable air flow impedance elements by consulting a database (e.g., look up table) that identifies the appropriate settings for the air flow impedance elements according to the configuration of the hardware modules.

The common air flow impedance may be determined to increase the efficiency of the one or more fans providing the air flow through the hardware modules in the enclosure. The controller may communicate with the air flow impedance system to position air flow impedance elements within the path of air flow through each hardware module to achieve the common air flow impedance for each hardware module. Accordingly, the air flow thorough the plurality of hardware modules may be balanced, thereby increasing the efficiency of the fans in each enclosure.

More particularly, in one example of the present disclosure, a method is provided for balancing air flow impedance within an enclosure. The method may include determining a configuration of each hardware module of a plurality of hardware modules arranged in a housing of the enclosure. The method may also include determining impedance settings for a plurality of adjustable air flow impedance elements within the housing, based at least in part on the configurations of the plurality of hardware modules, that will balance air flow impedances of the plurality of hardware modules. The method may further include setting the plurality of adjustable air flow impedance elements according to the determined impedance settings.

In another example of the present disclosure, an enclosure is provided and may include a housing, a plurality of hardware modules, a fan, an air flow impedance system, a controller, and a computer-readable storage medium. The plurality of hardware modules may be arranged in the housing. The fan may create an air flow through the plurality of hardware modules. The air flow impedance system may be disposed in the housing and may include a plurality of adjustable air flow impedance elements corresponding to the plurality of hardware modules. Each of the adjustable air flow impedance elements may selectively impede the air flow through the hardware module corresponding therewith. The controller may be configured to communicate with the air flow impedance system and the plurality of hardware modules. The computer-readable storage medium may include instructions executable by the controller to: determine a configuration of each hardware module; determine impedance settings for the plurality of adjustable air flow impedance elements, based at least in part on the configurations of the plurality of hardware modules, that will balance air flow impedances of the plurality of hardware modules; and set the plurality of adjustable air flow impedance elements according to the determined impedance settings.

In another example of the present disclosure, a non-transitory computer-readable medium is provided and includes computer executable instructions stored thereon that when executed by a processor, cause the processor to: determine a configuration of each hardware module of a plurality of hardware modules arranged in a housing of an enclosure; determine impedance settings for a plurality of adjustable air flow impedance elements within the housing, based at least in part on the configurations of the plurality of hardware modules, that will balance that air flow impedances of the plurality of hardware modules; and set the plurality of adjustable air flow impedance elements according to the determined impedance settings.

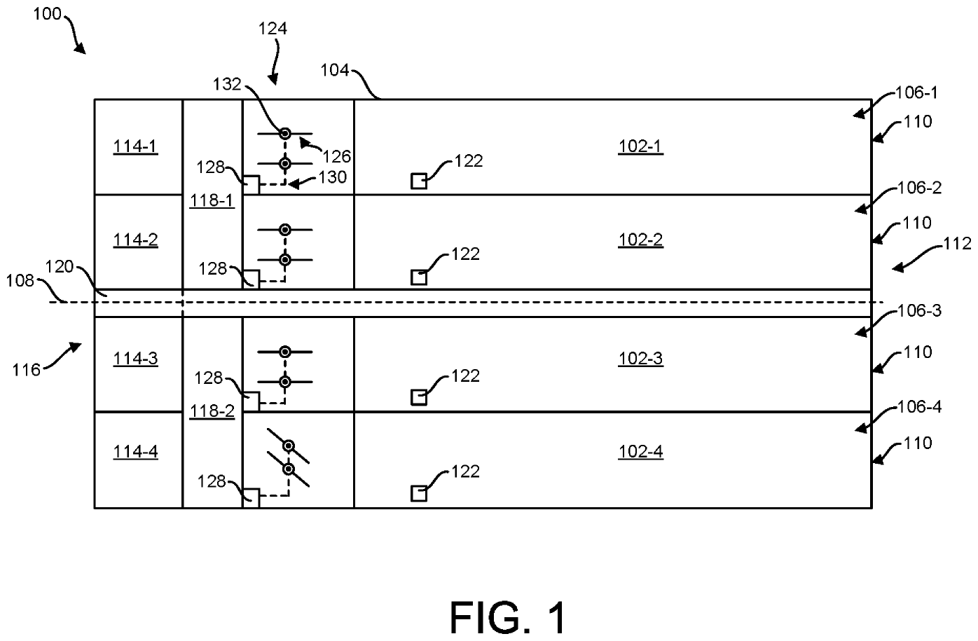

Turning now to the drawings, FIG. 1 is a schematic of an enclosure 100, according to one or more examples of the disclosure. The enclosure 100 may be installed in a server rack (not shown) along with a plurality of other enclosures in a stacked arrangement. The server rack may be a cabinet in which case the stack of enclosures including enclosure 100 may be completely enclosed. In one or more implementations, a plurality of server racks and accompanying infrastructure may be included in a datacenter (not shown).

The enclosure 100 may include a plurality of hardware modules 102-1 through 102-4 (also referred to collectively as hardware modules 102 or individually and generally as a hardware module 102) operating in conjunction with one another to form at least in part an electrical system. In one or more implementations, the electrical system may be part of a data center electrically coupled to an electrical power grid (not shown) to receive input power therefrom. The type and number of hardware modules 102 contained or otherwise housed in the enclosure 100 may vary depending on the architecture of the electrical system and the intended function thereof. Example hardware modules 102 may include, but are not limited to, computing devices (e.g., servers), storage devices (e.g., HDDs), and memory devices (e.g., DIMMs).

The enclosure 100 may be referred to in some implementations as a server chassis or a blade enclosure depending at least in part on the hardware modules 102 contained therein. For example, in implementations in which the enclosure 100 houses a plurality of blade servers, the enclosure 100 may be referred to as a blade enclosure. For purposes of this disclosure, the term “enclosure” may be understood to reference a “server chassis”, a “blade enclosure”, or a like component.

Generally, the enclosure 100 includes a housing 104 defining a plurality of compartments or bays 106-1 through 106-4 (also referred to collectively as bays 106 or individually and generally as a bay 106). As illustrated in FIG. 1, the bays 106 are arranged in a parallel manner with respect to a longitudinal axis 108 of the housing 104, thereby providing parallel paths for air flow therethrough. Each bay 106 may be sized and configured to receive therein a hardware module 102 through a respective opening 110 of the bay 106 in a front end 112 of the enclosure. However, it will be appreciated that one or more bays 106 may remain empty (i.e., no hardware module 102 is installed therein) or may have a hardware module 102 removed therefrom during operation of the electrical system (and, optionally, replaced with another hardware module 102, i.e., hot swapped). As provided herein, the term “hot swapped” may refer to the removal of a hardware module 102 and the physical connection of a replacement hardware module 102 to an interconnect (not shown) of the enclosure 100 while the electrical system is powered on.

In some implementations, the hardware module 102 may be or may include a server (not otherwise shown), such as a blade server. In other implementations, the hardware module 102 may be one or more computing devices, storage devices, and/or memory devices mounted on a tray (not otherwise shown) sized and configured to be contained in a respective bay 106 of the enclosure 100. In yet other implementations, the enclosure 100 may include both servers and trays in respective bays 106.

The enclosure 100 may include one or more fans. As illustrated in FIG. 1, the enclosure includes a plurality of fans 114-1 through 114-4 (also referred to collectively as fans 114 or individually and generally as a fan 114). The location and number of the fans 114 within the enclosure 100 may vary, and in the illustrated example, the fans 114 are disposed at a rear end 116 of the enclosure 100. Each fan 114 may be fluidly coupled to one or more bays 106 via an air plenum. As illustrated in FIG. 1, fans 114-1 and 114-2 may be fluidly coupled to bays 106-1 and 106-2 via a first air plenum 118-1, and fans 114-3 and 114-4 may be fluidly coupled to bays 106-3 and 106-4 via a second air plenum 118-2. As arranged, the fans 114 may draw air from the front end 112 of the enclosure 100 through the bays 106 and air plenums 118 and exhaust the air out of the rear end 116 of the enclosure 100, thereby creating a forced air flow through the hardware modules 102 to cool the hardware modules 102 and thus remove heat generated by the electrical components of the hardware modules 102 during operation of the electrical system.

As illustrated in FIG. 1, the enclosure 100 may further include a controller 120, a plurality of sensors 122 (four shown), and an air flow impedance system 124. The controller 120 may be communicatively coupled to the air flow impedance system 124, the plurality of sensors 122, and each of the hardware modules 102 inserted in the enclosure 100. In some implementations, the controller 120 may be communicatively coupled to the air flow impedance system 124, the plurality of sensors 122, and each of the hardware modules 102 via a wired connection. In other implementations, the controller 120 may be communicatively coupled to the air flow impedance system 124, the plurality of sensors 122, and each of the hardware modules 102 via a wireless connection. In yet other implementations, the controller 120 may be communicatively coupled to the air flow impedance system 124, the plurality of sensors 122, and each of the hardware modules 102 via a combination of wired and wireless connections. Although the controller 120 is illustrated in FIG. 1 as being internal to the housing 104 of the enclosure 100, in one or more implementations, the controller 120 may be external to the housing 104 of the enclosure 100 or distributed across components external to and internal to the housing 104 of the enclosure 100.

As illustrated, each sensor 122 of the plurality of sensors 122 may be located within a respective bay 106 of the enclosure 100. In another implementation, each sensor 122 may be located on a respective hardware module 102 disposed in each bay 106. In other implementations, the sensors 122 may be omitted. The number and locations of the sensors 122 will be implementation-specific depending on a multitude of factors such as the type of hardware module 102, the size of the bay 106 relative to the hardware module 102, etc. The plurality of sensors 122 may measure the temperature of each bay 106 and/or hardware module 102 disposed in each bay 106 on a continuous, periodic, or aperiodic basis and transmit the measured temperatures to the controller 120. The controller 120 may utilize the temperature measurements of the bays 106 and/or hardware modules 102 to determine, in part, the common air flow impedance of the enclosure 100, which will be discussed in greater detail below.

The air flow impedance system 124 may be positioned within the enclosure 100 upstream of the fans 114 and downstream from the bays 106, as defined by the forced air flow and as illustrated in FIG. 1. In other implementations, the air flow impedance system 124 may be disposed upstream of the bays 106 at the front end 112 of the enclosure 100. The air flow impedance system 124 may be configured to adjust or otherwise affect the air flow impedance in one or more bays 106 of the enclosure 100 as initiated by the controller 120. To that end, in the illustrated implementation of FIG. 1, the air flow impedance system 124 includes a plurality of adjustable air flow impedance elements 126 (only one indicated) and an actuator 128 (four shown) operatively coupled to the adjustable air flow impedance elements 126 to position the adjustable air flow impedance elements 126 accordingly to adjust the air flow impedance of each bay 106 as mandated by the controller 120.

In one or more implementations, the actuator 128 may be or may include a servo coupled to the adjustable air flow impedance elements 126 via one or more linkages 130. In other implementations, the actuator 128 may be or may include a plurality of servos coupled to the adjustable air flow impedance elements 126 via one or more linkages 130. Accordingly, in one or more implementations, the adjustable air flow impedance elements 126 may be operatively connected to the actuator(s) 128 via separate linkages 130 such that respective impedance element assemblies (adjustable air flow impedance elements 126 coupled to the same linkage 130) positioned in the flow path of each bay 106 may be positioned independently of one another. As such, the impedance element assembly in the flow path of one bay (e.g., 106-3) may be positioned independently of the impedance element assembly in the flow path of another bay (e.g., 106-4).

In one or more implementations, the plurality of adjustable air flow impedance elements 126 may be or may include a plurality of baffles (not separately shown). The size and structural configuration of the baffles may vary and may be based in part on the air flow in the enclosure 100. For example, the baffles may be shaped to reduce detrimental acoustic or aerodynamic effects. In some implementations, the baffles may be flat plates. In other implementations, the baffles may have an airfoil shape. However, it will be appreciated by those having the benefit of this disclosure that the shape of the baffles may include any suitable shape for providing an air flow impedance as mandated by the controller 120.

As illustrated in FIG. 1, the adjustable air flow impedance elements 126 may be oriented to rotate about an axis 132 (only one indicated) substantially perpendicular to the longitudinal axis 108 of the enclosure 100. To that end, the adjustable air flow impedance elements 126 may rotate such that the adjustable air flow impedance elements 126 are parallel to the direction of the air flow through the bay (e.g., 106-1 through 106-3) (i.e., 100% open) or are at an angle between about one degree and about ninety degrees from the direction of air flow through the bay (e.g., 106-4, about 50% open). As provided above, the adjustable air flow impedance elements 126 may be rotated via the actuator 128 (e.g. servo(s)) based on a communication received from the controller 120.

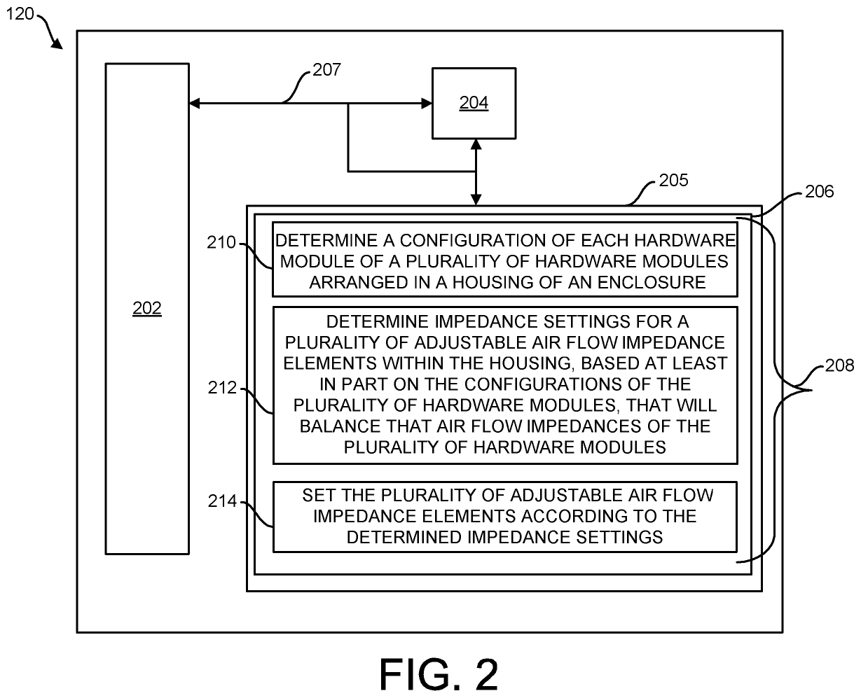

Referring now to FIG. 2 with continued reference to FIG. 1, FIG. 2 is a block diagram of selected portions of the controller 120 utilized in the enclosure of FIG. 1, according to one or more examples of the disclosure. The controller 120 may include a communications interface 202, one or more processors (one shown 204), and memory 205 including non-transitory computer-readable medium 206. The communication interface 202 may be communicatively coupled to the air flow impedance system 124, the plurality of sensors 122, each of the hardware modules 102, and the processor(s) 204. The non-transitory computer-readable medium 206 may be communicatively coupled to the processor(s) 204 and the communications interface 202 via a bus system 207.

As illustrated in FIG. 2, the non-transitory computer-readable medium 206 may store instructions 208 that, when executed by the processor(s) 204, cause the processor(s) 204 to: determine a configuration of each hardware module of a plurality of hardware modules arranged in a housing of an enclosure (block 210); determine impedance settings for a plurality of adjustable air flow impedance elements within the housing, based at least in part on the configurations of the plurality of hardware modules, that will balance that air flow impedances of the plurality of hardware modules (block 212); and set the plurality of adjustable air flow impedance elements according to the determined impedance settings (block 214).

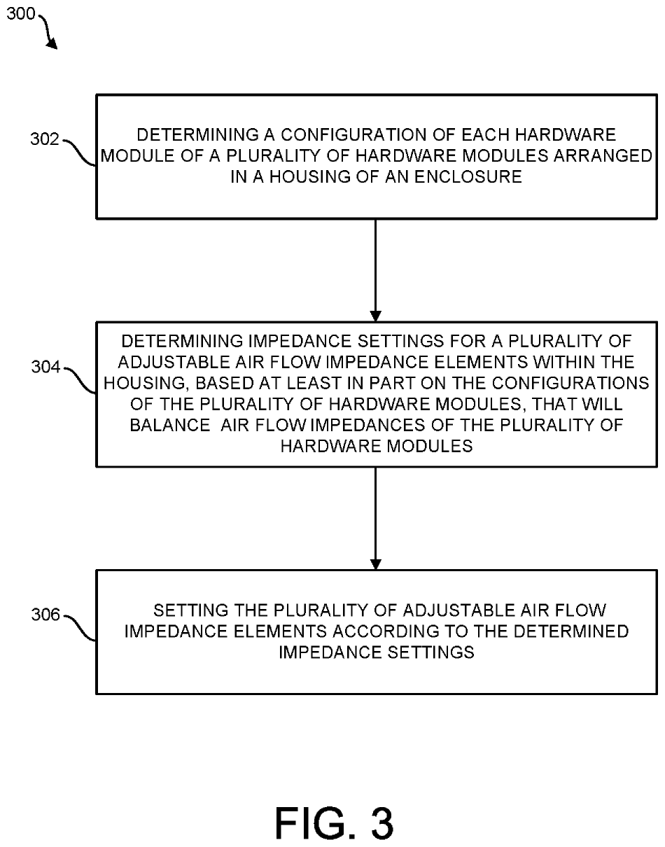

Moreover, the instructions 208 may be configured to cause the processor 204 to perform any of the operations of the methods 300, 400, and/or 500, shown in FIGS. 3-5, respectively, which are described in greater detail below. The non-transitory computer-readable storage medium 206 may be integrated in the controller 120 as shown in FIG. 2, or the non-transitory computer-readable storage medium 206 may be separate from but accessible to the controller 120.

In one example, the stored instructions 208 may be part of an installation package that when installed may be executed by the processor(s) 204 to implement the air flow impedance system 124 as provided in more detail below. In this case, the non-transitory computer-readable storage medium 206 may be a portable medium such as an optical disk (e.g., compact disc (CD) or digital video disc (DVD)), or flash drive or a memory maintained by a server from which the installation package can be downloaded or installed. In another example, the stored instructions 208 may be part of an application or applications already installed. Here, the non-transitory computer-readable storage medium 206 may include integrated memory such as hard drive, solid state drive, and the like.

Although the example illustrated in FIG. 2 shows the controller 120 being implemented with a processor 204 that is to execute instructions 208, it should be understood that the controller 120 may also be implemented, in whole or in part, using dedicated hardware, such as application-specific integrated circuits (ASICs), complex programmable logic devices (CPLD), and so on. In general, the controller 120 may include logic that is to: determine a configuration of each hardware module of a plurality of hardware modules arranged in a housing of an enclosure; determine impedance settings for a plurality of adjustable air flow impedance elements within the housing, based at least in part on the configurations of the plurality of hardware modules, that will balance that air flow impedances of the plurality of hardware modules; and set the plurality of adjustable air flow impedance elements according to the determined impedance settings, and this logic may include any combination of processors (such as the processor(s) 204), machine readable instructions (such as the instructions 208), and dedicated hardware.

Example methods 300, 400, and 500 for balancing the air flow impedance within an enclosure, such as the enclosure 100, will now be discussed, in the context of FIGS. 1 and 2, and with reference to FIGS. 3-5. The example methods 300, 400, and/or 500 may be performed, for example, at least in part by a controller associated with the enclosure 100, such as the controller 120. For example, the controller 120 may execute instructions 208 that causes the controller 120 to perform some or all of the operations of the methods 300, 400, and/or 500. As another example, the controller 120 may include dedicated hardware that performs some or all of the operations of the methods 300, 400, and/or 500.

Referring now to FIG. 3 with continued reference to FIG. 1 and FIG. 2, FIG. 3 is a flowchart depicting a method 300 for balancing air flow impedance within an enclosure, according to one or more examples of the disclosure. In discussing FIG. 3, reference is made to the enclosure 100 of FIG. 1 and the controller 120 of FIG. 1 and FIG. 2 to provide contextual examples. Implementation, however, is not limited to those examples.

The method 300 may start at block 302 and may include determining a configuration of each hardware module 102 of a plurality of hardware modules 102 arranged in the housing 104 of the enclosure 100. The method 300 may also include determining impedance settings for the plurality of adjustable air flow impedance elements 126 within the housing 104, based at least in part on the configurations of the plurality of hardware modules 102, that will balance air flow impedances of the plurality of hardware modules 102 (block 304). The method 300 may further include setting the plurality of adjustable air flow impedance elements 126 according to the determined impedance settings, as at block 306.

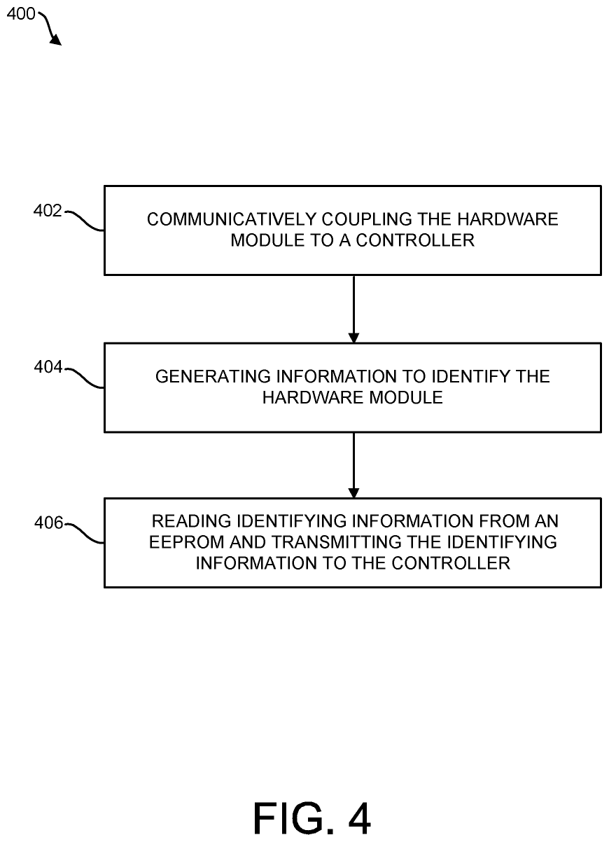

Referring now to FIG. 4 with continued reference to FIGS. 1-3, FIG. 4 is a flowchart depicting a method 400 for determining the configuration of each hardware module 102 arranged in the housing 104 of the enclosure 100, as implemented in block 302 of FIG. 3, according to one or more examples of the disclosure. In discussing FIG. 4, reference is made to the enclosure 100 of FIG. 1 and the controller 120 of FIG. 1 and FIG. 2 to provide contextual examples. Implementation, however, is not limited to those examples.

The method 400 may start at block 402 and may include communicatively coupling the hardware module 102 to the controller 120. This may be carried out by installing the hardware module 102 in a bay 106 of the enclosure 100 and connecting the hardware module 102 to an interconnector, such as a midplane or backplane connector (not shown). At block 404, the hardware module 102 may generate information to identify the hardware module 102. The identifying information may be based on firmware of one or more electronic components installed in the hardware module 102. In one or more implementations, the identifying information may be written to an Electrically Erasable Programmable Read-Only Memory (EEPROM) (not otherwise shown) of the hardware module 102.

The identifying information may include information pertaining to the configuration of each insertable component. As at block 406, the identifying information may be read from the EEPROM and transmitted to the controller 120. A device discovery module (not otherwise shown) stored in the non-transitory computer-readable storage medium 206 may receive the identifying information and may determine the configuration of the hardware module 102 therefrom.

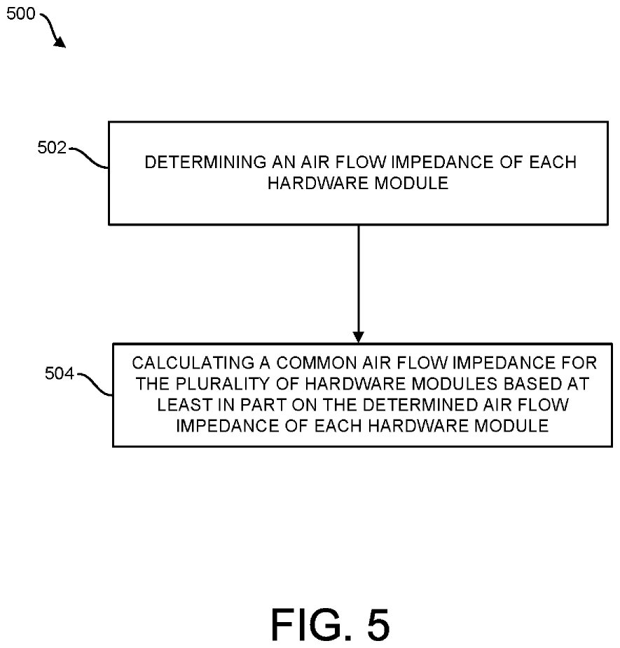

Referring now to FIG. 5 with continued reference to FIGS. 1-3, FIG. 5 is a flowchart depicting a method 500 for determining impedance settings for the plurality of adjustable air flow impedance elements 126 within the housing 104, based at least in part on the configurations of the plurality of hardware modules 102, that will balance air flow impedances of the plurality of hardware modules 102, as implemented in block 304 of FIG. 3, according to one or more examples of the disclosure. In discussing FIG. 5, reference is made to the enclosure 100 of FIG. 1 and the controller of FIG. 1 and FIG. 2 to provide contextual examples. Implementation, however, is not limited to those examples.

The method 500 may start at 502 and may include determining the air flow impedance of each hardware module 102. In one or more implementations, the air flow impedance of each hardware module 102 may be determined based on computer modeling or other computer-related fluid testing results stored in memory 205. At block 504, the method 500 may include calculating a common air flow impedance for the plurality of hardware modules 102 based at least in part on the determined air flow impedance of each hardware module 102. In one or more implementations, the calculation may be carried out from a matrix of solutions based on a respective constant assigned to each air flow impedance of a respective hardware module 102. In some implementations, the calculations may be based on plotted data associated with the flow dynamics of the enclosure 100. The calculation of the common air flow impedance may be carried out to increase the efficiency of the fan(s) 114 positioned within the housing 104 and creating an air flow through the plurality of hardware modules 102.

In one or more implementations, the common air flow impedance may be determined in part based on the temperature of the hardware modules 102 and/or the bays 106 in which the hardware modules 102 are housed. The controller 120 may receive temperature measurements from each of the hardware modules 102 and/or the bays 106 in which the hardware modules 102 are housed. Based on the air flow impedance of each hardware module 102 and the temperature measurement of each hardware module 102 and/or bays 106 in which the hardware modules 102 are housed, a common air flow impedance is determined via a calculation (or plot). Accordingly, the balancing of the air flow impedance may be dynamic, as the temperature readings may be taken on a continuous, periodic or aperiodic basis, and the common air flow impedance may be calculated on a continuous, periodic, or aperiodic basis, resulting in a dynamic common air flow impedance. Such a dynamic response is useful in instances in which the workload of a particular hardware module 102 may increase during certain operations.

Likewise, the balancing of the air flow impedance within the enclosure 100 may be dynamic with regard to determining the common air flow impedance based on the determined configuration of each hardware module 102. For example, in instances in which a hardware module 102, such as a blade server, is hot-swapped or hot-plugged, the controller 120 may determine the configuration of the hardware module 102. Being hot-plugged means that the hardware module 102 is physically connected to an interconnect (not shown) of the enclosure 100 while the electrical system is powered on. Based on the configuration of the blade server, the air flow impedance of the hardware module 102 may be determined. Based on the air flow impedance of the hardware module 102 and the remainder of the hardware modules 102, a common air flow impedance may be determined. As the foregoing may occur at each instance of hot swapping, the balancing of the air flow impedance may be dynamic, as the hot swapping of hardware modules 102 may occur on a periodic or aperiodic basis, and the common air flow impedance may be calculated on such a basis, resulting in a dynamic common air flow impedance.

In another example method for determining impedance settings for the plurality of adjustable air flow impedance elements 126 within the housing 104, as implemented in block 304 of FIG. 3, the method may include referencing, via the controller 120, a look up table for predetermined impedance settings of the adjustable air flow impedance elements 126 based on the determined configurations of the plurality of hardware modules 102. For example, with reference to FIG. 1, the controller 120 may determine that the hardware modules 102 include three compute trays (e.g., 102-1 through 102-3) and one memory tray (e.g., 102-4), the controller 120 may reference the look up table and determine that the adjustable air flow impedance elements 126 of the compute trays 102-1 through 102-3 are to be positioned to 100% open, and the adjustable air flow impedance elements 126 of the memory tray 102-4 are to be positioned to 50% open).

Referring back now to FIG. 3 with continued reference to FIG. 1 and FIG. 2, setting the plurality of adjustable air flow impedance elements 126 according to the determined impedance settings, as at block 306, may include positioning, via the actuator 128, one or more adjustable air flow impedance elements 126 in a respective air flow path of each hardware module 102 independently of one or more adjustable air flow impedance elements 126 disposed in respective air flow paths of the other hardware modules 102. In one or more implementations, the adjustable air flow impedance elements 126 may be grouped in impedance element assemblies according to the positioning thereof in the respective air flow paths of the hardware modules 102. Accordingly, each impedance element assembly may move independently of the other impedance element assemblies to provide individual air flow impedance settings for each hardware module 102 to customize the desired air flow impedance for each hardware module 102 to balance the air flow impedances of the plurality of hardware modules 102.

Generally speaking, the airflows through the hardware modules are “balanced” when the same volumetric flow rate is achieved through each module. Similarly, the impedances of the hardware modules are “balanced” when they all have the same effective impedance. However, it should be understood that, in practice, perfect balancing of the volumetric flow rates and impedances may not always be possible or desirable. Thus, airflows or impedances may be considered to be “approximately” balanced when the difference between the highest value of the airflows or impedances (Xₘₐₓ) and the lowest value of the airflows or impedances (Xₘᵢₙ) is less than 10% of the highest airflow or impedances, that is when Xₘₐₓ−Xₘᵢₙ<0.1·Xₘₐₓ. Similarly, the airflows or impedances may be considered to be “significantly” balanced when Xₘₐₓ−Xₘᵢₙ<0.05·Xₘₐₓ. Furthermore, references herein and in the appended claims to an action improving or increasing the balance between the airflows or impedances should be understood to mean that the action decreases the quantity Xₘₐₓ−Xₘᵢₙ.

As used herein, a “processor” may include any circuitry that is capable of executing machine-readable instructions, such as central processing units (CPUs), microprocessors, microcontrollers, digital signal processors (DSPs), field-programmable gate arrays (FPGAs), application-specific instruction set processors (ASIPs), etc.

As provided above, examples in the present disclosure may also be directed to a non-transitory computer-readable medium storing computer-executable instructions and executable by one or more processors of the computer via which the computer-readable medium is accessed. A computer-readable media may be any available media that may be accessed by a computer. By way of example, such computer-readable media may include random access memory (RAM), read-only memory (ROM), electrically erasable programmable read-only memory (EEPROM), compact disk read-only memory (CD-ROM) or other optical disk storage, magnetic disk storage or other magnetic storage devices, or any other medium that may be used to carry or store desired program code in the form of instructions or data structures and that may be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Note also that the software implemented aspects of the subject matter claimed below are usually encoded on some form of program storage medium or implemented over some type of transmission medium. The program storage medium is a non-transitory medium and may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The claimed subject matter is not limited by these aspects of any given implementation.

Furthermore, examples disclosed herein may be implemented by hardware, software, firmware, middleware, microcode, hardware description languages, or any combination thereof. When implemented in software, firmware, middleware or microcode, the program code or code segments to perform the necessary tasks (e.g., a computer-program product) may be stored in a machine-readable medium. A processor(s) may perform the necessary tasks.

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific examples are presented for purposes of illustration and description. They are not intended to be exhaustive of or to limit this disclosure to the precise forms described. Obviously, many modifications and variations are possible in view of the above teachings. The examples are shown and described in order to best explain the principles of this disclosure and practical applications, to thereby enable others skilled in the art to best utilize this disclosure and various examples with various modifications as are suited to the particular use contemplated. It is intended that the scope of this disclosure be defined by the claims and their equivalents below.

1. A method for balancing air flow impedance within an enclosure, comprising:
determining a configuration of each hardware module of a plurality of hardware modules arranged in a housing of the enclosure, wherein each of the hardware modules has an associated intrinsic air flow impedance, and one or more of the hardware modules has a highest intrinsic air flow impedance;
determining impedance settings for a plurality of adjustable air flow impedance elements within the housing, based at least in part on the configurations of the plurality of hardware modules, that will increase a total air flow impedance, across one or more of the hardware modules, to match the highest intrinsic air flow impedance to balance air flow impedances of the plurality of hardware modules; and
setting the plurality of adjustable air flow impedance elements according to the determined impedance settings.

2. The method of claim 1, wherein the configuration of each hardware module is determined based on firmware of the respective hardware module.

3. The method of claim 1, wherein determining the impedance settings for the plurality of adjustable air flow impedance elements within the housing, further comprises:
determining the intrinsic air flow impedance of each hardware module based on the configuration of each hardware module;
determining the highest intrinsic airflow impedance; and
determining a common air flow impedance for the plurality of hardware modules based at least in part on the determined air flow impedance of each hardware module, wherein the common air flow impedance equals the highest intrinsic air flow impedance.

4. The method of claim 1, wherein:
the plurality of adjustable air flow impedance elements includes a plurality of baffles corresponding to the plurality of hardware modules, each of the baffles to selectively impede air flow through the hardware module corresponding therewith; and
setting the plurality of adjustable air flow impedance elements according to the determined impedance settings, further comprises:
positioning, via an actuator, one or more baffles in a respective air flow path of each hardware module independently of one or more baffles disposed in respective air flow paths of the other hardware modules.

5. The method of claim 1, wherein:
a plurality of sensors is disposed in the housing, each sensor to detect a temperature of a respective hardware module of the plurality of hardware modules; and
determining the impedance settings for the plurality of adjustable air flow impedance elements is further based in part on the temperature of each hardware module.

6. The method of claim 1, wherein the plurality of hardware modules includes at least one of a tray and a server.

7. The method of claim 1, wherein the plurality of adjustable air flow impedance elements is disposed upstream of a fan and downstream from the plurality of hardware modules.

8. An enclosure comprising:
a housing;
a plurality of hardware modules arranged in the housing, wherein each of the hardware modules has an associated intrinsic air flow impedance, and one or more of the hardware modules has a highest intrinsic air flow impedance;
a fan to create an air flow through the plurality of hardware modules;
an air flow impedance system disposed in the housing and including a plurality of adjustable air flow impedance elements corresponding to the plurality of hardware modules, each of the adjustable air flow impedance elements to selectively impede the air flow through the hardware module corresponding therewith;
a processor configured to communicate with the air flow impedance system and the plurality of hardware modules; and
a computer-readable storage medium comprising instructions executable by the processor to:
determine a configuration of each hardware module;
determine impedance settings for the plurality of adjustable air flow impedance elements, based at least in part on the configurations of the plurality of hardware modules, that will increase a total air flow impedance, across one or more of the hardware modules, to match the highest intrinsic air flow impedance to balance air flow impedances of the plurality of hardware modules; and
set the plurality of adjustable air flow impedance elements according to the determined impedance settings.

9. The enclosure of claim 8, wherein:
the air flow impedance system further includes an actuator communicatively coupled to the controller; and
the plurality of adjustable air flow impedance elements includes a plurality of baffles operatively coupled to the actuator such that one or more baffles may be disposed in a respective air flow path of each hardware module and positioned independently of the one or more baffles disposed in the respective air flow paths of the other hardware modules.

10. The enclosure of claim 8, wherein the plurality of adjustable air flow impedance elements is disposed upstream of the fan and downstream from the plurality of hardware modules.

11. The enclosure of claim 8, further comprising a single air plenum fluidly coupling the plurality of hardware modules and the fan.

12. The enclosure of claim 8, further comprising:
a plurality of sensors, each sensor to detect a temperature of a respective hardware module of the plurality of hardware modules,
wherein the instructions executable by the processor to determine the impedance settings for the plurality of adjustable air flow impedance elements is further based in part on the temperature of each hardware module.

13. The enclosure of claim 8, wherein the plurality of hardware modules includes at least one of a tray and a server.

14. The enclosure of claim 8, wherein the configuration of each hardware module is determined based on firmware of the respective hardware module.

15. The enclosure of claim 8, wherein the instructions executable by the processor to determine impedance settings for the plurality of adjustable air flow impedance elements, based at least in part on the configurations of the plurality of hardware modules, that will balance air flow impedances of the plurality of hardware modules is further executable by the processor to:
determine the intrinsic air flow impedance of each hardware module based on the configuration of each hardware module;
determine the highest intrinsic airflow impedance associated with the plurality of hardware modules; and
determine a common air flow impedance for the plurality of hardware modules based at least in part on the determined air flow impedance of each hardware module, wherein the common air flow impedance equals the highest intrinsic air flow impedance.

16. A non-transitory computer-readable medium comprising computer executable instructions stored thereon that when executed by a processor, cause the processor to:
determine a configuration of each hardware module of a plurality of hardware modules arranged in a housing of an enclosure, wherein each of the hardware modules has an associated intrinsic air flow impedance, and one or more of the hardware modules has a highest intrinsic air flow impedance;
determine impedance settings for a plurality of adjustable air flow impedance elements within the housing, based at least in part on the configurations of the plurality of hardware modules, that will increase a total air flow impedance, across one or more of the hardware modules, to match the highest intrinsic air flow impedance balance that air flow impedances of the plurality of hardware modules; and
set the plurality of adjustable air flow impedance elements according to the determined impedance settings.

17. The non-transitory computer-readable medium of claim 16, wherein the configuration of each hardware module is determined based on firmware of the respective hardware module.

18. The non-transitory computer-readable medium of claim 16, wherein the computer executable instruction that when executed by the processor, causes the processor to determine the impedance settings for the plurality of adjustable air flow impedance elements within the housing, further causes the processor to:
determine the intrinsic air flow impedance of each hardware module based on the configuration of each hardware module;
determine the highest intrinsic airflow impedance associated with the plurality of hardware modules; and
determine a common air flow impedance for the plurality of hardware modules based at least in part on the determined air flow impedance of each hardware module, wherein the common air flow impedance equals the highest intrinsic air flow impedance.

19. The non-transitory computer-readable medium of claim 16, wherein:
the plurality of adjustable air flow impedance elements includes a plurality of baffles corresponding to the plurality of hardware modules, each of the baffles to selectively impede air flow through the hardware module corresponding therewith; and
the computer executable instruction that when executed by the processor, causes the processor to set the plurality of adjustable air flow impedance elements according to the determined impedance settings, further causes the processor to:
position, via an actuator communicatively coupled to the processor, one or more baffles in a respective air flow path of each hardware module independently of one or more baffles disposed in respective air flow paths of the other hardware modules.

20. The non-transitory computer-readable medium of claim 16, wherein:
a plurality of sensors is disposed in the housing, each sensor to detect a temperature of a respective hardware module of the plurality of hardware modules; and
the computer executable instructions that, when executed by the processor, cause the processor to determine the impedance settings for the plurality of adjustable air flow impedance elements is further based in part on the temperature of each hardware module.
